(19) United States
(12) Patent Application Publication
(10) Pub. No.: US 2008/0265306 A1
(43) Pub. Date: Oct. 30, 2008

(54) Non-Volatile Memory Device Having a Gap in the Tunnuel Insulating Layer and Method of Manufacturing the Same

(75) Inventors: Robertus Theodorus Fransiscus Van Schaijk, Eindhoven (NL); Michiel Jos Van Duuren, Valkenswaard (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/097,144

(22) PCT Filed: Dec. 11, 2006
(86) PCT No.: PCT/IB06/54741

§ 371 Date: Jun. 12, 2008

(30) Foreign Application Priority Data
Dec. 15, 2005 (EP) 05112188.7
Dec. 11, 2006 (IB) PCT/IB2006/054741

(51) Int. Cl. H01L 29/792; H01L 21/336

(52) U.S. Cl. 257/324; 438/287; 257/E29.309

(57) ABSTRACT

A non-volatile memory device (1, 101, 201, 301) having a gap within a tunnel dielectric layer (14, 114, 214, 314) and a method of manufacturing the same is provided. The devices have a stack of layers on top of a substrate (10, 110, 210, 310) including, a charge tunneling layer with a gap (14, 114, 214, 314), a charge storage layer (16, 116, 216, 316), a control gate layer (20, 120, 220, 320) and an insulating layer (18, 118, 218 220) in between the charge storage layer and the control gate. Manufacturing proceeds through deposition of a sacrificial layer (28, 128,228,328) on parts of a substrate, whereupon a stack of layers (24, 124,224,324) including a charge-storage layer, an insulating layer and a control gate layer are formed. Subsequently, selected parts of the sacrificial layer are removed, thereby forming a gap in between the charge storage region and the substrate. The gap is protected from future processing by deposition of a sealing layer (34, 134, 234, 334). Such a device has a reduced operating voltage and its manufacture can be easily implemented in existing semiconductor processes.

The present invention relates to a non-volatile memory device and an apparatus comprising such a device. Such devices may be used in stand-alone or embedded non-volatile memories (NVM), such as for instance electrically erasable programmable read-only memories (EEPROM) or Flash. The invention further relates to a method of manufacturing such a device.

A non-volatile memory device generally constitutes a transistor device, comprising a source region, a drain region and a channel region in between said drain and source region, formed in a silicon semiconductor substrate, as well as a charge storage region (CSR), formed above the substrate between the channel region and an electrically conducting control gate usually made of highly doped polysilicon. The charge storage region is separated and electrically insulated from the substrate by a tunnel dielectric layer and from the control gate by an insulating layer.

Within conventional devices the CSR consists of a floating gate, which is made of heavily doped polysilicon. In this case the insulating layer is called the interpoly dielectric (IPD). The amount of charge present on the floating gate determines the threshold voltage of the transistor and therewith the memory state of the device.

In other devices the threshold voltage differentiation is brought about by storing charge locally in an electrically insulating, charge trapping dielectric (CTD) layer instead of in a conducting floating gate. These devices generally have a stack of layers consisting of a Silicon transistor channel, a siliconOxide tunnel dielectric, a siliconNitride CTD, a siliconOxide insulator (comparable to the IPD) and a Silicon control gate and are called SONOS devices.

To ‘read’ the charge state of a memory transistor, i.e. to determine whether it is ‘programmed’ or ‘erased’, the magnitude of the current from source to drain is measured at a predefined control gate voltage. Programming is accomplished by application of a voltage to the control gate with respect to the source/drain or substrate, such that field induced movement of charge from the channel region to the CSR through the tunnel dielectric layer occurs by means of tunneling. Application of an opposite voltage difference results in discharging and is called ‘erasing’. These programming and erasing voltages are substantially higher than those used in contemporary Complementary Metal Oxide Semiconductor (CMOS) devices of for example peripheral or control circuitry.

Within the semiconductor industry, shrinkage of device dimensions to reduce cost and to increase integration level necessitates operating voltages to be reduced. For a non-volatile memory transistor, in particular the high control gate voltage needs to be reduced.

In order to be able to supply the lowest voltage to the control gate of such a memory transistor, the voltage must be efficiently transferred to the charge storage layer through capacitive coupling.

To lower the supply voltage, hitherto the thickness of the tunnel dielectric layer and/or of the insulating layer was reduced, but this cannot continue due to fundamental materials properties that do not scale with size. Most importantly, the charge (data) retention time of a memory transistor requires a minimum thickness for both aforementioned layers in order to minimize charge loss through leakage to such values that the standard industry retention specification can be met.

Different solutions for lowering the control gate voltage have been sought. One of them is described in U.S. Pat. No. 6,861,307 B2. In this device the dielectric constant (k) of the insulating layer between control gate and charge storage layer is equal to or higher than that of the tunnel dielectric layer. The tunnel dielectric layer may comprise a tunnel dielectric material with a low dielectric constant (e.g. low k). The top dielectric layer may be a dielectric material with a high k. Preferably the material is selected from the group of Al₂O₃, HfO₂, HfSiₓO_{y}, ZrO₂ or ZrSiₓO_{y} and other materials with similarly high k values. However the document does not discloses suitable low-k tunnel dielectric materials. Furthermore, the practical use of high-k materials has profound drawbacks, such as difficult and expensive integration in the semiconductor manufacturing processes due to materials property incompatibilities and contamination issues, resulting in reduced reliability of the memory device.

It is an object of the present invention to provide a non-volatile memory device, which has a reduced operating voltage and which can be easily manufactured. A device as defined in claim 1 realizes the aforementioned objects.

The present invention provides a non-volatile memory device comprising: a substrate, a first layer including a charge storage region and a second layer including a charge-tunneling region comprising a gap, said second layer being arranged in between said substrate and said first layer.

The invention is based on the insight that the replacement of a solid-state tunnel dielectric material such as siliconoxide with a material that comprises a gap has unexpected advantages. Such a replacement significantly reduces the k value from for example 3.9 of siliconoxide as a tunneling material to 1.0 for a gap extending through the entire tunnel region being substantially vacuum. The reduced k value results in lower program and erase voltages.

Moreover, a tunneling barrier increase associated with said replacement results in improved data retention. This improvement can at least partly be used to decrease the thickness of the tunnel gap, as compared to the thickness of the original solid-state tunnel dielectric layer to such an extent that the standard industry retention specification is still met. In a preferred embodiment, the advantage of having a charge tunneling region according to the invention is in the larger coupling between a control gate and a CSR, which results in lowering of the control gate voltage without requiring high-k materials for the insulating layer between the control gate and the charge storage region.

A further aspect of the invention is an advantageous manufacturing method for devices having such a charge-tunneling region, as specified in independent claim 6. Thus a method according to the invention comprises the steps of providing a sacrificial layer on selected parts of the substrate, followed by its partial removal after deposition of other device layers on top of said sacrificial layer at selected positions, whereby said removal is selective against other device layers. Said steps may be performed using procedures and equipment that can be easily implemented in a conventional semiconductor manufacturing process, such as used for CMOS production, enabling cheap and reliable process integration.

When the possibility of reduction of the thickness of the charge-tunneling region according to the present invention is not exploited to decrease the operating voltage, the memory device has an improved reliability and data retention time.

An advantage of having a charge tunneling region comprising a gap is that materials incompatibility issues at solid-solid interfaces, which lead to adverse stress phenomena within for example the charge tunneling layer and/or the charge storage layer, are reduced or absent.

Furthermore, the amount of electronic traps, and other defects, associated with a solid-state material tunnel region, are reduced in the device according to the present invention. Therewith, trap assisted leakage currents or stress induced leakage currents (SILC), will advantageously be reduced too. This will result in improved charge retention times, endurance and an intrinsically higher breakdown voltage increasing the device reliability.

A further advantage of a gap within the charge-tunneling region is that during operation, in particular during programming and erasing of the device, the formation of traps or defects in said region is reduced. This will reduce the development of reliability problems during operation; such as for instance threshold voltage shifts, breakdown phenomena or reduced data retention due to leakage.

In a preferred embodiment of the present invention the gap extends through the entire first layer, i.e. the tunnel region then essentially consists of a gap. Hence the entire tunnel region will then benefit from all advantages associated with the gap as explained above and below. Furthermore, if said gap is substantially vacuum, said tunnel region will have the ultimately low k value of 1, which, moreover, is temperature independent and yields the largest drop in operating voltage on the control gate.

In another embodiment the gap within the tunnel region may comprise a gas or a liquid, which preferably has a low polarity and/or a low polarisability such that its k value is low. In this document, “gas” as well as “liquid” includes pure substances or their mixtures, which are in gaseous or liquid state respectively, under operating conditions of the device. Liquid herein also includes materials such as glasses. For example gases like air, oxygen and hydrogen or inert gases like nitrogen and argon will have k values approximating 1. Non-polar organic substances such as for example hydrocarbons like hexane or benzene have k values of around 2. Filling the gap with such substances may be advantageous, since vacuum conditions need not be maintained during or after manufacturing of said device. Hence, conditions such as for example gas or liquid pressure may be determined by processing steps prior to, during, or after sealing of said gap. Furthermore, such substances may be used to adjust charge-tunneling properties.

In a preferred embodiment of the present invention the non-volatile memory device has a charge storage layer comprising electrically conducting material. Said conducting materials include for example metals and their alloys or (highly) doped semiconductors such as polysilicon. In this configuration, the tunnel layer according to the present invention can be incorporated in standard industry floating gate transistor devices, thus simplifying adaptation of design, processing and operating schemes.

In another embodiment of the present invention the non-volatile memory device has an insulating layer wherein charge is stored as electrons or holes in traps, so that the charge cannot move or displace freely through the charge storage region, as is the case with a conducting charge storage region. Usually a siliconnitride layer is used to trap charge. Devices making use of this charge trapping principle and a tunnel region according to the present invention will have a lower operating voltage than their counterparts with conducting charge storage layers. In addition, since the stored charge is not free to move within the charge storage region, the presence of defects within the charge-tunneling region according to the present invention will result in reduced leakage of stored charge. Hence the device will have improved reliability. Examples of defects may be dirt particles or other unwanted substances introduced during processing.

The present invention also provides a method for manufacturing a non-volatile memory device, comprising the steps of: providing a substrate, depositing a sacrificial layer on first selected parts of the substrate, forming on first selected parts of said sacrificial layer a stack of layers comprising a first layer having a charge storage region and selectively removing second selected parts of the sacrificial layer, thereby forming a gap in between said first layer and the substrate.

The formation of a gap according to the present invention is enabled by this method, since removal of the sacrificial layer is selective with respect to all other parts of the substrate and its components, which are, or will become exposed to the conditions during the removal process.

Furthermore, the process enables that a gap or a multitude of gaps can be formed on a predefined position, or according to a predefined pattern on the substrate, since formation and/or removal of said sacrificial layer can be performed using selective growth or patterning techniques. This is important when it is appreciated that all functional device layers, stacked on top of said sacrificial layer, need to remain physically sustained by and attached to the substrate after said removal of the sacrificial layer to form the gap. An advantage in this respect is evident when the memory device needs to be combined with other electrical devices such as for instance selection transistors, which do not require the tunnel region according to the present invention.

The method has the advantage of easy process integration, since introduction of materials with high-k, or low-k values, which are incompatible with conventional semiconductor manufacturing processes, are avoided.

In a preferred embodiment the method includes deposition of a sacrificial layer that comprises silicon and germanium. For example a layer of silicongermanide (SiₓGe₁₋ₓ), where 0<x<1, may be used. Apart from facile deposition and patterning, such a layer can also be grown selectively on predefined parts of the substrate, thereby eliminating a patterning step. Furthermore, such a silicongermanide layer can be etched using standard fluorine containing plasma dry etch techniques, which are performed using equipment and conditions similar to those used for other etch steps that are frequently used in semiconductor manufacturing processes. Thus easy process integration and possible combination of process steps to reduce their number is enabled.

In a preferred embodiment, the gap is sealed. The advantage of sealing said gap is that if other process steps to form e.g. interconnect in back-end-of-line processes were to be conducted after formation of said gap, said other steps could contaminate or fill up said gap.

In a further preferred embodiment the step of sealing the gap includes the formation of offset spacers. Such offset spacers are advantageously provided when the non-volatile-memory device is a transistor device. Within such devices, the offset spacers are used for source and drain impurity ion implantation. It is advantageous to seal said gap using materials that are normally used for making the offset spacers, since then the combined steps of sealing and spacer formation reduce processing time and cost. In addition, easy implementation of the sealing step in the manufacturing process is enabled.

In one embodiment the gap is filled with a gas or liquid before sealing of said gap is finished. The presence of a gas or liquid within a gap after said sealing may be due to the sealing step process conditions. Alternatively, sealing of the gap may be performed in such a way that the environment within the gap may be determined as desired. Thus, for example, the gap could be filled with a chosen liquid having specific electrical properties using capillary force before it is sealed.

In an embodiment the memory device is part of an apparatus having a non-volatile memory. For example, the device may be part of a stand-alone non-volatile memory, in which case peripheral circuitry could be used for operating the memory device. It may for example be part of a memory card incorporating NAND flash memory for mass data storage. Alternatively, the device according to the present invention could be part of an embedded memory, in which case besides peripheral circuitry present to operate the memory devices other functional circuitry is integrated. Furthermore, in either type of non-volatile memory, each memory device may be connected to a selection device, said selection device providing electrical connection to a wordline and to a bitline of a 2- or 3-dimensional array of a defined size. Said selection device allows operating individual memory devices. Said selection device may for example be a diode or a transistor.

These and other aspects of the invention will be further elucidated and described with reference to the drawings, in which:

FIG. 1 is a schematic vertical cross section of a floating gate transistor comprising a tunnel gap;

FIG. 2 is a schematic vertical cross section of the device of FIG. 1 viewed in a direction perpendicular to that of FIG. 1;

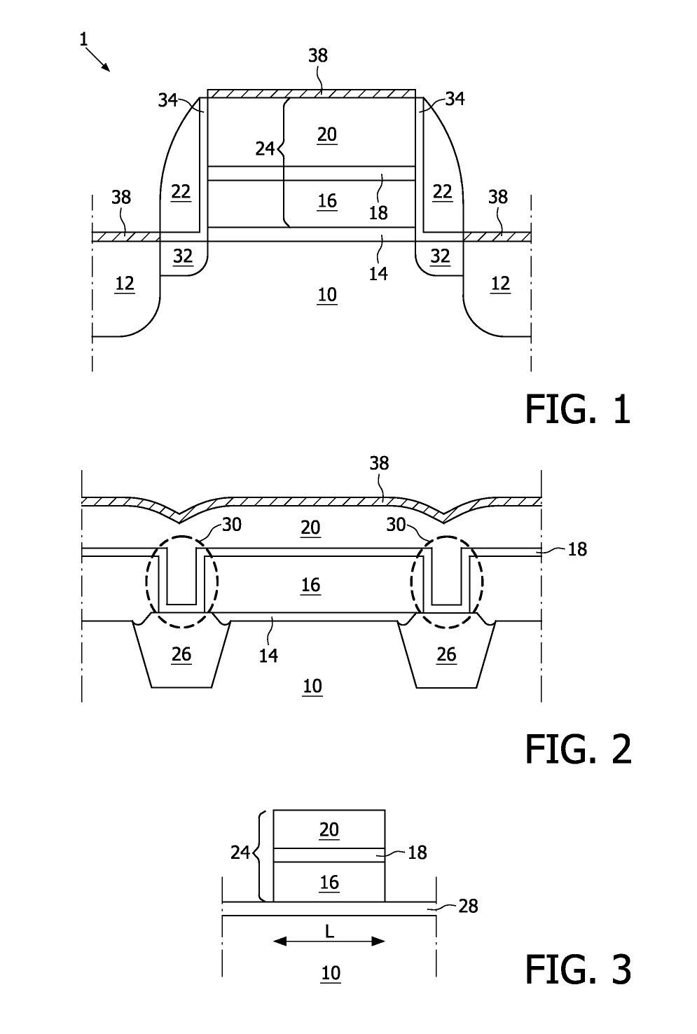

FIG. 3 is a schematic vertical cross section of a floating gate stack on a substrate surface with a sacrificial layer;

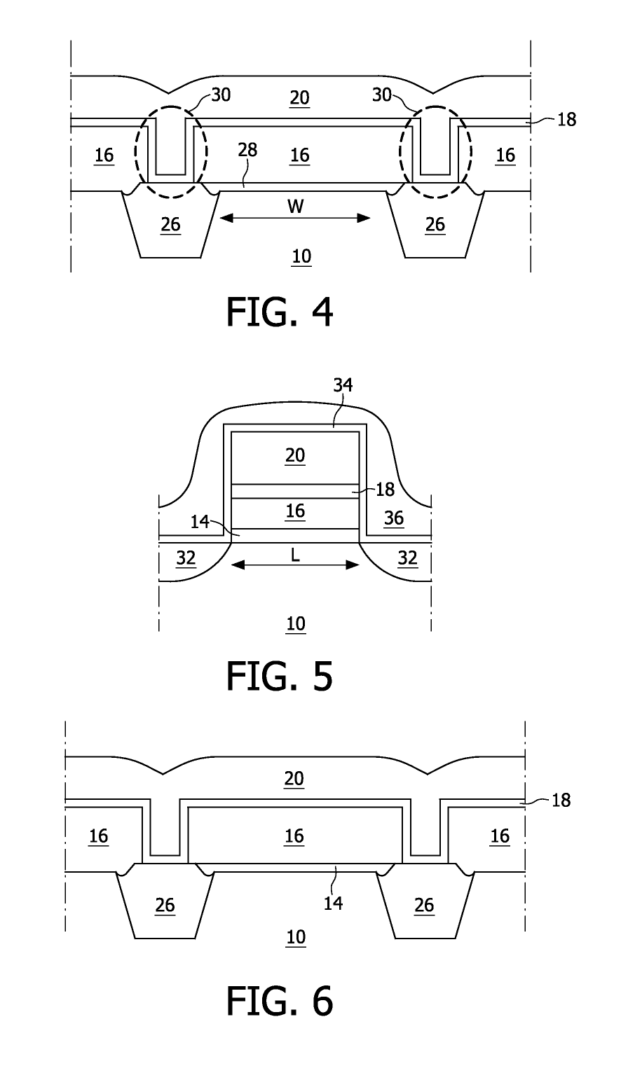

FIG. 4 is a schematic vertical cross section of the floating gate stack of FIG. 3, viewed in a direction perpendicular to that of FIG. 3;

FIG. 5 is a schematic vertical cross section of the floating gate stack of FIG. 3, after formation of a blanket layer;

FIG. 6 is a schematic cross section of the stack of FIG. 5, viewed in a direction perpendicular to that of FIG. 5;

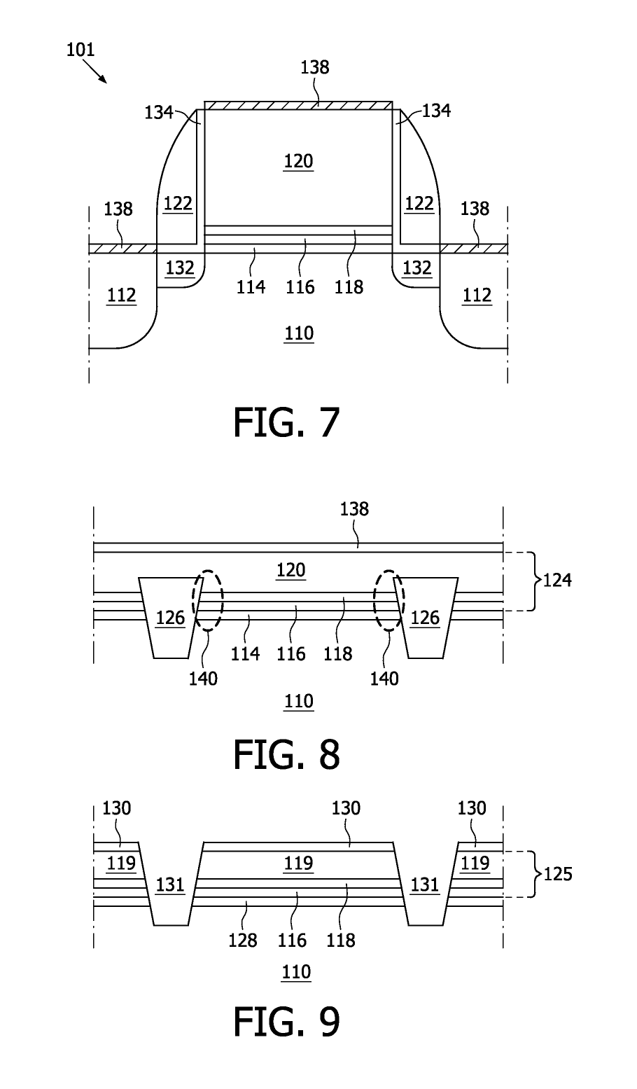

FIG. 7 is a schematic vertical cross section of a STNOS device prepared using STI;

FIG. 8 is a schematic vertical cross section of the device of FIG. 7 viewed in a direction perpendicular to that of FIG. 8;

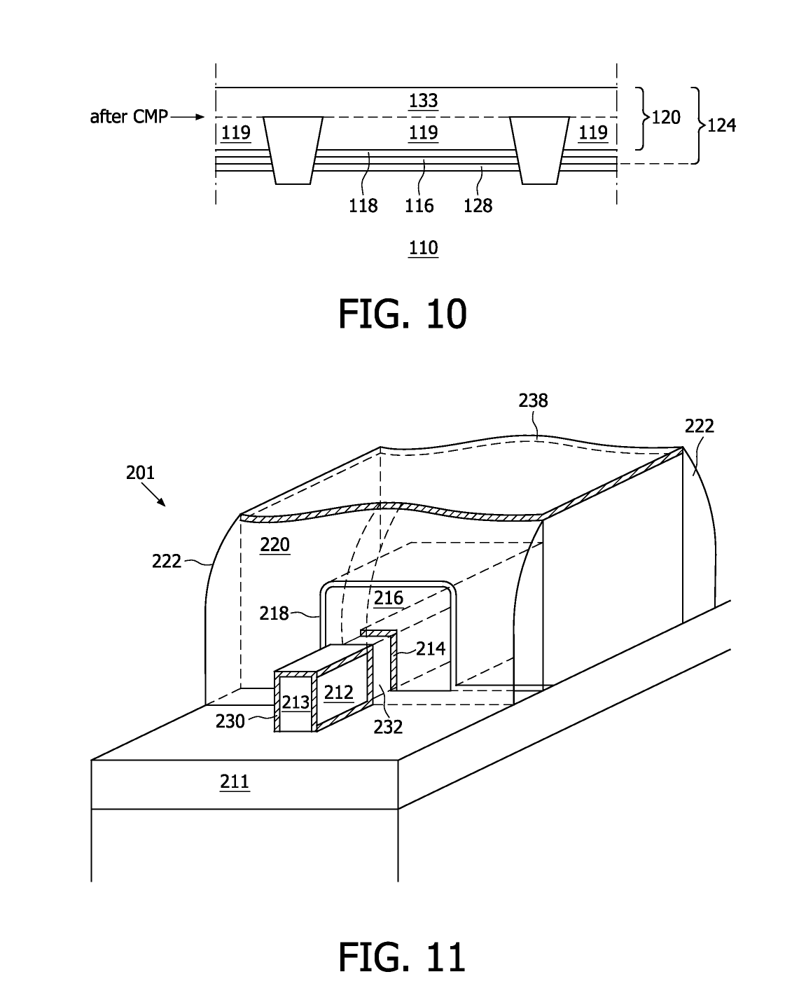

FIGS. 9 and 10 are schematic vertical cross sections of two stages of manufacturing of the STNOS cell of FIG. 8;

FIG. 11 is a schematic perspective view of a FGfinFET device;

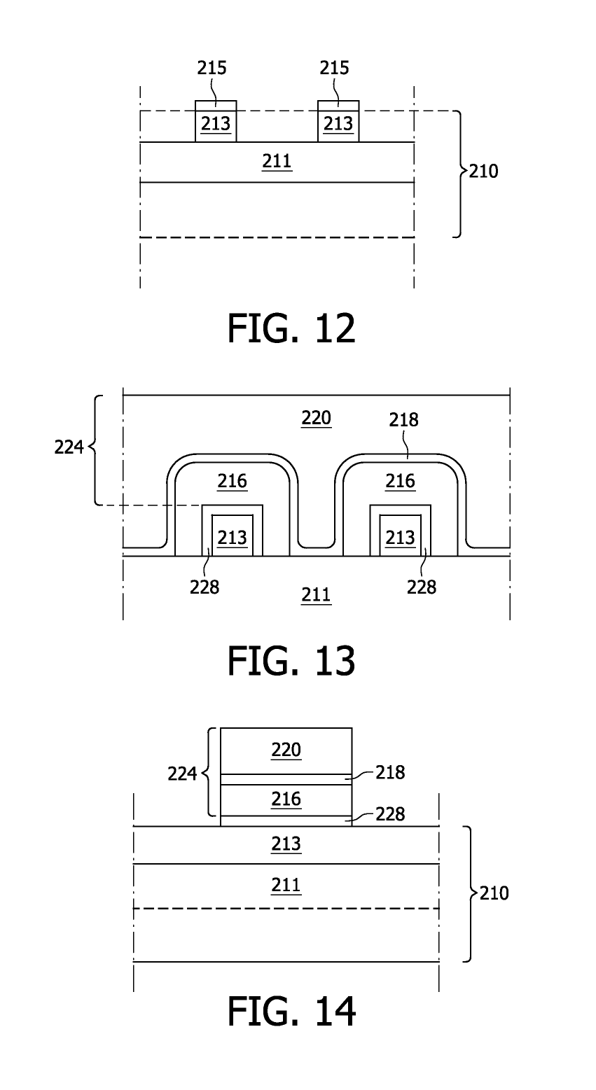

FIGS. 12 to 15 are schematic vertical cross sections of various stages during manufacturing of the FGfinFET of FIG. 11, and

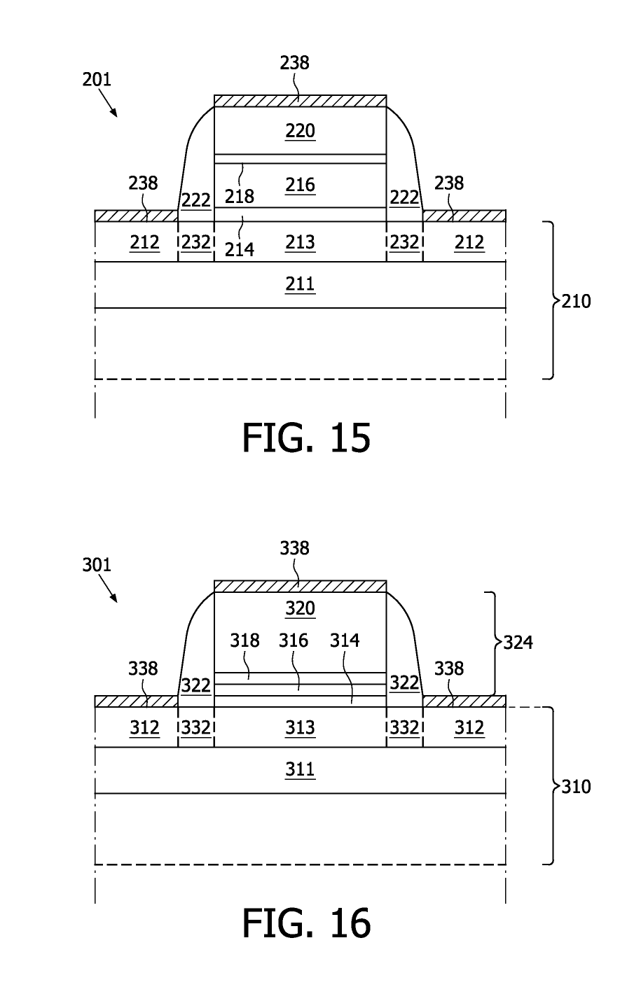

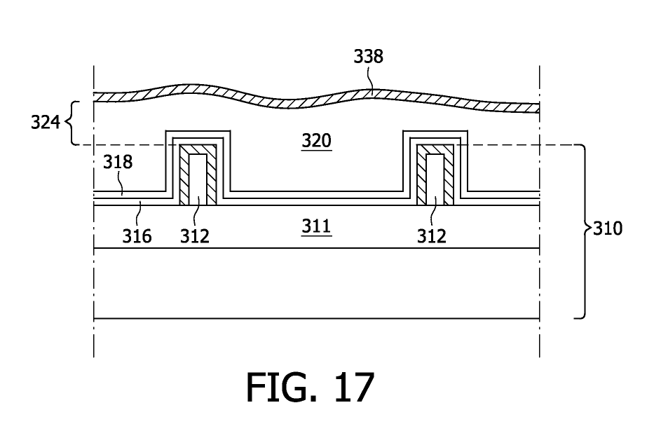

FIGS. 16 and 17 are schematic vertical cross sections of STNOSfinFET devices observed form perpendicular directions.

According to the present invention, in a first step, a substrate is provided. In embodiments of the present invention the term ‘substrate’ may include any underlying material or materials that may be used, or upon which a device, a circuit or layer may be or has been formed. Examples of semiconductor substrates are: doped silicon, galliumarsenide (GaAs), gallium arsenidephosphide (GaAsP), germanium (Ge), or silicongermanide SiGe. The substrate may include, for example, an insulating layer such as silicondioxide or siliconnitride in addition to a semiconductor substrate portion. Thus the term substrate also includes: silicon-on-insulator, silicon-on-glass (SOG), silicon-on-saphire (SOS) and silicon-on-anything (SOA). The term substrate is thus used to generally define the elements for layers that underlie a layer or portions of interest. Furthermore, the substrate may be any other base on which a layer is formed, said layer being for example a glass or metal layer. Furthermore, it is noted that the substrate need not have a flat surface.

Corresponding layers or features in the memory devices of the embodiments described below have like numerals.

As a first embodiment of a memory device 1 according to the present invention, a floating gate transistor device, as schematically shown in FIGS. 1 and 2, is described. The main features of such a device include a substrate 10, with source and drain regions 12, a gap 14 forming the charge-tunneling region (“tunnel gap”), a conducting floating gate 16, an insulating region 18 (IPD), a conducting control gate 20 and a sealing layer 34, which is part of the sidewall spacers 22. The gate stack 24 comprising layers 16, 18 and 20.

Said device may be prepared by a method as described hereafter referring to FIGS. 3 and 4. In a first step, a p-type silicon semiconductor substrate 10 is provided, having field oxide isolation 26 prepared using a shallow trench isolation (STI) procedure. The distance between the neighboring isolation parts define the active silicon area wherein the transistors channel region with dimensions W and L would be positioned. As known to those skilled in the art, next to the memory element other devices, such as for example selection transistors, may be present. Alternatively, other types of field isolation may be provided by for example a LOCOS procedure or a selective epitaxial growth procedure.

Selected parts of the substrate 10, such as said active silicon area might be provided with suitable doping profiles, i.e. impurity ion implantations to create n- and/or p-type wells or retrograde wells containing anti punch-through implants and/or threshold voltage shift implants. In addition, if necessary, e.g. for particular memory types or operating schemes, all of the aforementioned, doped regions may be contained in a n-type buried layer so as to form a triple well structure. Moreover source and drain implants may be provided at this stage of the manufacturing method to form for example buried bitlines. All doping profiles can be provided with the appropriate impurity ions with the necessary doses using procedures known by those skilled in the art.

On top of said substrate 10, a sacrificial silicongermanide (SiₓGe₁₋ₓ) layer 28, having a thickness of for example 5-10 nm, is formed on exposed active silicon parts of the substrate using a selective epitaxial growth process. The germanium content (1-x) in layer 28 preferably is relatively high since higher germanium content results in higher selectivity toward silicon during etching of said layer 28. However, it is noted that a critical germanium content exists beyond which unwanted delaminating of layer 28 from the substrate 10 occurs due to stress accumulation that is too high. For example, in J. Appl. Phys. 83 (1998) 171 it is described that a critical germanium content in a SiₓGe₁₋ₓ layer exists as a function of the thickness of this layer. In this document it is also described that provision of a silicon capping layer on top of the sacrificial layer allows the use of higher germanium contents, which may be advantageous when devices with a conducting floating gate comprising silicon are prepared. Without the silicon capping layer, germanium contents lower than 30, 35, 40, 50 or 60% can be used for preparation of layers thinner than 7, 5, 3.5, 2.2 or 1.5 nm, respectively.

The use of a selective growth procedure for the silicongermanide sacrificial layer 28, has the advantage over non-selective deposition techniques, such as for example LPCVD or wet deposition, that no patterning step needs to be performed. In this respect it is noted that said sacrificial layer will be removed from the substrate in a later part of the manufacturing process, necessitating the formation of regions or areas that allow parts of layers and structures that have been built on top of the sacrificial layer to remain physically attached to the substrate 10 at so called anchor points, thus assuring device integrity. In an advantageous embodiment said patterning of the silicongermanide layer 28 is combined with an etch step performed in a later stage of the method, thus reducing the number of process steps.

If patterning of layer 28 is needed at this stage of the manufacturing process, it may be accomplished using for example an anisotropic plasma etch technique such as a reactive ion etch (RIE) using atomic fluorine from precursors such as CF₄ or SF₆. Also isotropic wet etching may be employed to remove parts of the sacrificial layer.

On top of layer 28 a first polysilicon layer 16 is deposited to a thickness preferably between about 50 and 400 nm, in which at a later stage of the process the floating gate of the memory device is defined. Said deposition is preferably done by chemical vapor deposition (CVD) using for example a silane ambient. Doping of the polysilicon layer 16 with arsine or phosphorus impurity ions can be done during deposition of said polysilicon layer 16 via for example addition of arsine or phosphine derivatives to said silane ambient. Alternatively, an intrinsic polysilicon layer can be deposited and subjected to an impurity-ion implantation procedure.

In an alternative embodiment the floating gate may comprise other conducting materials including for example amorphous silicon or metals. Examples of said metals include TiN and TaSiN that can be deposited using for example CVD or other techniques as known by those skilled in the art.

Said first polysilicon layer 16 is patterned with slits 30 so as to define and isolate those parts of layer 16 that will become floating gate transistors connected to a same wordline but different bitlines. Said etching can be done with for example plasma RIE.

In a next step an IPD layer 18, is formed over said patterned first polysilicon layer 16. Said IPD layer 18 may comprises an insulating material such as silicondioxide, thermally grown, or deposited using for example LPCVD or plasma enhanced CVD (PECVD). The IPD layer 18 preferably comprises other insulating materials such as is the case for an ONO composite layer, which may be deposited using methods as known to those skilled in the art. Said IPD layer 18 may have a thickness of about 10 to 30 nm.

In an embodiment the IPD layer 18 may comprise a high-k material such as for example Al₂O₃, HfO₂, HfSiₓO_{y}, ZrO₂ or ZrSiₓO_{y} deposited using for example a LPCVD technique or a rapid thermal chemical vapor deposition (RTCVD) process. Said IPD layer 18 comprising high-k material may be deposited to a thickness of for example 5 to 30 nm. It is to be noted that the desired thickness is related to the actual k-value of the constituents of said layer 18 and the desired control gate to floating gate capacitive coupling in conjunction with the optimization of other memory cell parameters such as data retention and reliability.

After forming the IPD layer 18 a second polysilicon layer 20 is deposited with properties and using techniques as for example described for polysilicon layer 16.

Alternatively the control gate may be prepared from other conducting materials, as described for the floating gate layer 16.

After the deposition of layers 16, 18 and 20 has been finished, said layers are anisotropically etched according to a pattern defined by a suitable photoresist or hard mask in order to define the gate stack 24 comprising layers 16, 18 and 20 as shown in FIG. 3. The hard mask may be for example a siliconnitride layer deposited and patterned according to standard lithographic procedures. Etching of stack 24 may be performed using for example plasma RIE. In the present example, said RIE etch is stopped on the sacrificial layer 28, but it could also be stopped on the substrate 10 such that material of the sacrificial layer 28 is only left in between the gate stack 24 and the substrate 10.

In a next step the parts of layer 28 remaining on the substrate after said gate stack etch has been finished, are etched and removed in order to open the desired tunnel gap 14 in between the gate stack 24 and the substrate 10 as shown in FIGS. 5 and 6. This can be accomplished using an isotropic wet etching or a dry etching technique, which removes layer 28 selectively with respect to parts of the device that are exposed before etching or will become exposed during etching. Said other substrate parts include for example all exposed layers of said gate stack 24 including not only the polysilicon of the floating gate layer 16 and control gate layer 20, but also the isolating materials of the IPD layer 18. In addition it is noted that during said etching the substrate body surface material at the positions of the channel region as well as the STI 26 will become exposed, requiring etch selectivity toward these parts also. It will also be clear that in case the memory device is part of a larger device or circuitry the above selectivity must hold for all of their parts also. As mentioned above, etch selectivity of layer 28 toward silicon may be enhanced by increasing for example the Germanium content within the sacrificial layer 28. A dry etching technique such as for example a chemical plasma CF₄ RIE is preferred, since it has the advantage of using chemical components and equipment that enable this step to be incorporated in the same process step as said etching of the gate stack 24, thus resulting in facile and cheap process implementation.

If not already present, doping regions in the substrate 10 may be formed to prepare for example self-aligned lightly doped drains (LDD) or medium doped drains (MDD) 32 that define the transistor channel length L as shown in FIG. 5. Said doping profiles need not be the same on both sides of the transistor channel. Also other or additional doping profiles such as for example drain and/or source pocket implants may be provided as desired. Note that these doping steps may be combined with those required for forming conventional MOS transistors of peripheral circuitry if present on the substrate, thus saving process cost and time. All doping profiles exhibiting the appropriate impurity ions in the necessary doses can be provided using conventional procedures as known to those skilled in the art.

In a following step the tunnel gap 14 is sealed or closed to prevent filling during subsequent processing steps. Said sealing can be done by for example deposition of a blanket layer 34 over the substrate and the gate stack 24 as shown in FIG. 5. To reduce process steps the sealing step can be combined with the formation of offset spacers 22 shown in FIG. 1. In that case said spacers 22 may be prepared by first depositing a PECVD siliconoxide layer 34 having a thickness of the order of that of the IPD layer 18. Then a PECVD siliconnitride layer is deposited to a thickness of for example 30-100 nm to form the body of the spacer 22 after plasma etch back with a stop on for example the substrate 10. The result of said sealing and offset spacer formation is shown in FIG. 1. Instead, a single layer sealing spacer can be made by deposition of a 30-100 nm thick PECVD siliconoxide blanket layer that is etched back. Alternatively, or when no offset spacers are required, other materials, such as for example aforementioned high-k materials, or deposition procedures can be used to seal the gap 14.

Subsequently the spacers 22 can serve as offset spacers for e.g. a highly doped drain (HDD) impurity ion implantation using known processing thus forming source and drain regions 12 as shown in FIG. 1.

To finish front-end-of-line processing of the device selected exposed silicon areas such as for example source drain regions 12 and the control gate 20 are provided with a conductive layer 38 using for example silicidation as known by those skilled in the art. Subsequently, standard back-end-of-line processing can be used to finish the circuitry containing the non-volatile memory device.

A device according to the first embodiment will have a significantly reduced operating voltage when compared to its conventional counterpart having a siliconoxide tunnel region. A value for the reduced operating voltage can be estimated when the different k values and tunnel barriers of a tunnel oxide and a tunnel gap are taken into account. The higher barrier for the tunnel gap enables to reduce the thickness of the tunnel layer in order to obtain a standard industry retention time.

For example, the 9 nm thick siliconoxide tunnel dielectric of a conventional floating gate transistor device can be replaced by a 6 nm thick gap. Assuming a relative dielectric constant of the IPD layer k_{IPD} of 3.9, an IPD layer thickness t_{IPD} of 15 nm and an area between control gate and floating gate A₁ of 12·10⁻¹⁴ m⁻², the capacitance between control gate and floating gate C_{CG} given by k_{IPD}A₁/t_{ipd} is 2.8·10⁻¹⁶ F. Further assuming a transistor channel length L of 0.2 μm, transistor channel width W of 0.2 μm, the capacitance between floating gate and substrate C_{CR} given by kₜᵣA₂/tₜᵣ, wherein A₂=W·L is 4·10⁻¹⁴ m². While for an oxide tunnel region with kₜᵣ=3.9 and thickness tₜᵣ=9 nm, C_{CR} is 1.5·10⁻¹⁶ F, for a tunnel gap with kₜᵣ=1.0 with a thickness tₜᵣ=6 nm, C_{CR} is 0.59·10⁻¹⁶ F. Neglecting other parasitic capacitances the control gate coupling factors (α) given by C_{CG}/(C_{CG}+C_{CR}) are calculated to be 0.65 for the conventional tunnel dielectric and 0.83 for the tunnel gap. Thus in this example an improvement of the coupling factor by about 20% is achieved, which translates into a similar reduction of the control gate voltage, thereby improving the scalability of the device.

In a further embodiment the control gate voltage can be further decreased beyond that caused by the tunnel gap, when the overlap area between control gate and floating gate is increased. This may for example be achieved by using conducting offset spacers as described for example in an embodiment of document WO 03/096431 A1.

In another embodiment of a non-volatile memory device 101 according to the present invention a charge trapping transistor device (STNOS) is described. It resembles a SONOS transistor device, the difference being that the tunnel oxide in the SONOS device is replaced by a tunnel gap in the STNOS device. This example reveals that the present invention is not restricted to the fabrication of floating gate transistor devices. Furthermore, although such a STNOS transistor may be prepared on a substrate that has been provided beforehand with field oxide as described for the floating gate transistor of FIG. 1, the STNOS transistor in the present embodiment is prepared in combination with a self-aligned STI, the advantages of which will become apparent from the description below. The self-aligned STI can also be used in conjunction with fabrication of a floating gate device according to the present invention.

The main features of a STNOS device according to the present invention are schematically shown in FIGS. 7 and 8, where such a device is depicted positioned on a substrate 110 and in between field oxide STI 126. Said features include source and drain regions 112 and source and drain extensions 132, a tunnel gap 114, a siliconnitride charge trapping layer 116 with on top a siliconoxide dielectric layer 118 to separated and insulate the charge trapping layer 116 from the conducting control gate 120. The thin layer 134, part of the sidewall spacer 122, seal said tunnel gap 114 from the side. Thus with respect to the conventional floating gate transistor of FIG. 1, the charge-trapping layer 116 has replaced the conducting floating gate 16 and the siliconoxide insulating layer 118 fulfills the role of the IPD layer 18 in FIG. 1. Note furthermore that the charge-trapping layer 116 in FIG. 7 is thinner than the floating gate layer 16 in FIG. 1, which reduces the overall height of the memory device and hence topography on a substrate, benefiting processing after finishing of the memory devices.

A device as described and represented in FIGS. 7 and 8 may be prepared with a method according to the present invention. As will become apparent from the description hereafter, a number of process steps of said method bear strong resemblance to the corresponding steps used for preparation of the floating gate transistor of FIG. 1. Thus, hereafter, only the processing steps that differ significantly or those that describe formation of new layers or features will be described in detail.

With reference to FIGS. 7 to 10, a substrate 110, which does not have field isolation provided on at least part of its surface and which may have its entire silicon surface area exposed, is provided with a sacrificial silicongermanide layer 128, as described for the floating gate device of the first example. Said sacrificial layer may have a thickness smaller than 10 nm but preferably between 1 and 5 nm as shown in FIGS. 9 and 10.

Subsequently, a stack of layers 125 is prepared on top of layer 128 comprising a siliconnitride layer 116, followed by a siliconoxide insulating layer 118 and a polysilicon layer 119. The complete stack could for example be deposited using CVD techniques as known to those skilled in the art. The siliconnitride charge-trapping layer 116 may for example have a thickness of about 6 nm and the siliconoxide insulating layer 118 may have a thickness of about 8 nm. The layer 119 may be deposited to a thickness of 50 nm.

In an alternative embodiment, the layers 116 and 118 may be prepared from other insulating materials provided that charge trapping is possible within layer 116 or for example at its interface with layer 118. Other insulating materials or their mixtures, which are able to trap charge, incorporated in a single layer or in stacked layer forms can also be used. In an embodiment the insulating layer 118 may be prepared as described for the IPD layer of the floating gate transistor of the first embodiment.

In a next step a stack of layers 125 is etched using for example plasma RIE and a patterned photoresist or siliconnitride hard mask 130, whereby etching is proceeded down into the silicon of substrate 110 to form the trenches 131 as shown in FIG. 9. In this example said etch step is also used to remove the sacrificial layer 128 at positions where it is not needed, i.e. for example at the anchor areas, where the STNOS transistor will be physically sustained and attached to the substrate 110.

The empty trenches 131 are filled with field oxide using STI processing with chemical mechanical polishing (CMP) and optional removal of the hard mask 130 to expose the first polysilicon layer 119 and the resulting STI 126 as shown in FIG. 10.

Next a second CVD polysilicon layer 133 is deposited to such a thickness that, when added to that of the polysilicon layer 119, the total polysilicon layer thickness equals that of a polysilicon layer 120 suitable for control gate formation. The result is shown in FIG. 10.

At this point of the process, layer 119 and 133 in FIG. 10 taken together as layer 120 correspond to the second polysilicon layer 20 of the floating gate transistor of FIG. 4. Therefore, the proceeding of the front-end-of-line processing of the STNOS from hereon, is similar to that described in FIGS. 4 to 6 for the floating gate transistor of the first embodiment. Briefly, this means that after etching stack 124 down to the substrate 110, source and drain extensions 132 are formed, the tunnel gap 114 is etched open and a sealing layer 134 with offset spacers 122 are formed. Then source and drain 112 as well as other doping profiles are provided. Finally a silicidation layer 138 is provided to finish front-end-of-line processing. Using the procedure as described in the present example, a STNOS device as pictured in FIGS. 7 and 8, comprising the tunnel gap is obtained, but which also has smooth borders between the transistor channel active region and the tunnel gap 114 and the STI 126 at positions 140. This improves the reliability of the device. A further advantage of the self-aligned procedure is that higher density memory arrays can be obtained.

A floating gate fin field-effect transistor (FGfinFET) 201 according to the present invention and as shown in FIG. 11 provides a third embodiment. A difference with the aforementioned embodiments is that the tunnel gap 214 is not entirely horizontally situated on the substrate 210 since the active silicon 213 surrounded by the tunnel gap 214 forms a ridge on the surface of the layer 211. Within the context of the present application, the active region 213 is considered as part of the substrate and the charge tunnel region comprising tunnel gap 214 is, again, arranged between the substrate and the charge storage region 216. Such a device as shown in FIG. 11 may be prepared according to the present invention, as described hereafter with reference to FIGS. 12 to 15. First a silicon-on-insulator (SOI) substrate 210 having a crystalline silicon layer 213, with a thickness of for example 50 nm on a siliconoxide layer 211 is provided with a suitable hard mask 215 of for example siliconnitride, which is patterned using for example optical or e-beam lithography. Subsequently, said crystalline silicon layer 213 is etched using for example plasma RIE in order to define the fin shaped active silicon regions 213 of what will become the FGfinFET device as shown in FIG. 12. The parts of the hard mask 215 remaining on top of the fin 213 are removed, but in other embodiments they may also be left in place and removed at a later stage of the process. It is to be noted that the active silicon of fin 213 underneath said remaining hard mask parts 215 is different from that on the vertical sides of the fin 213 due to different silicon crystal orientations, which may result in differences during subsequent processing, such as for example during formation of the sacrificial layer as described in the following paragraphs. Furthermore, along the different crystal orientations in one transistor channel of a FGfinFET different electrical behavior may occur due to for example different charge carrier mobilities.

As shown in FIG. 13, a sacrificial layer 228 of for example silicongermanide is grown on the fin 213 using a selective epitaxial growth procedure. However, as described in the first embodiment alternative deposition techniques can be used. In an embodiment a silicongermanide layer can be deposited over the entire substrate. Those skilled in the art will be able to choose the deposition method such that parts of layer 215 attached to the crystalline silicon of the fin 213 will be crystalline, whereas on top of the siliconoxide layer 211 of the substrate 210 it will be amorphous. Said amorphous parts of such a layer 228 can be removed selectively against the crystalline parts of layer 228 using a wet or dry etch technique.

Then a CVD polysilicon layer 216 is deposited and patterned using for example anisotropic plasma RIE as shown in FIGS. 13 and 14 to form the floating gate of the FGfinFET. To enhance conductivity of layer 216, it is doped with the appropriate impurity ion implants using known procedures. Doping may proceed before or after etching of layer 216. As described in the other examples of the present invention, the layer 216 may comprise other suitable materials such as metals or alloys of metals.

In a next step an IPD layer 218 is deposited as described for the corresponding layer in the first embodiment of the present invention. The IPD layer may for example be an alternating stack of steam grown siliconoxide, PECVD siliconnitride and steam grown siliconoxide, with a total thickness of for example 15 nm. In an alternative embodiment the IPD layer can be made of high-k materials as described in other embodiments.

A second polysilicon layer 220, wherein the control gate will be defined, is deposited with a thickness preferably between about 50 nm and 150 nm using the same deposition procedure as used for the first polysilicon layer 216. The result after finishing the gate stack 224, comprising layers 216, 218 and 220 is shown in FIG. 14. Note that the gate stack 224 is not always parallel with the substrate as it surrounds the active silicon fin 213 as shown in FIG. 13. Thus, also the tunnel gap 214 is not parallel to the substrate everywhere. Subsequently, said gate stack 224 is etched using, for example, an anisotropic plasma RIE etch with a stop on the active silicon fin 213 or the sacrificial layer 228 and layer 211, as shown in FIG. 14. Note that FIG. 14 is a vertical cross section of the FGfinFET of FIG. 11 at the position of the active silicon fin 213, viewed perpendicular with respect to the extension direction of said fin 211. Hence, all material or layers alongside the fin 211 in its direction of extension are not represented. In alternative embodiments etching is done as described for the first embodiment of the present invention, but it is not limited thereto. All etching procedures that leave the gate topography as depicted in FIG. 14 intact and which are selective toward all materials and constituents of the substrate, which are or will become exposed during etching, can be used.

The tunnel gap 214 can be opened by selectively etching the part of the sacrificial layer 228 that remains after gate stack etch, either only in between the active silicon fin 213 and the gate stack 224 or on the entire active silicon fin 213. Note that said remaining part of layer 228 surrounds the fin 213, as shown in FIG. 11 which is not immediately apparent from FIG. 14 due to aforementioned reasons of cross-sectional view. The preferred way for removing said remaining parts of layer 228 is by a dry etch technique as described in the first embodiment of the present invention. From FIG. 11 it is clear that etching does not need to proceed around corners in between said gate stack 224 and fin 213, since it proceeds substantially from the sides of the gate stack 224 along the direction of extension of the fin 213.

LDD or MDD doping regions 232 and/or other doping profiles may now be provided using techniques known to those skilled in the art. In an embodiment these or part of these doping profiles are provided before opening the tunnel gap 214.

To prevent filling of the tunnel gap 214 during subsequent processing, it is sealed using a procedure as described for the first embodiment of the present invention. The sealing step may be combined with the formation of offset spacers, which can be prepared by deposition of a blanket TEOS based siliconoxide layer of appropriate thickness, followed by anisotropic etching according to standard procedures to obtain the spacers 222 as shown in FIG. 15. Note that although not shown, in the present embodiment said spacer 222 extends down to the surface of the insulator 211, covering not only the top of the fin 213, but also its sides as shown in FIG. 11, thus sealing the entire tunnel gap 214. In another embodiment a conventional double layer offset spacer comprising for example siliconoxide and siliconnitride can be used.

Subsequently, impurity ion implants are used to enhance the conductivity of the control gate layer 220 and to form source and drain regions 212 within the active silicon fin 213.

Finally front-end-of-line processing is finished by deposition of a silicide layer 238 formed using a conventional silicidation process.

In a fourth embodiment a charge-trapping finFET 301 as for example schematically shown in FIGS. 16 and 17 may be prepared. Said device comprises a gate stack 324 around the tunnel gap 314 comprising a charge-trapping layer 316, an insulating layer 318 separating said layer 316 form the conducting control gate layer 320. As described for the STNOS device of the present invention the layer 316 may for example comprise siliconnitride, while the layer 318 may comprise silicondioxide such as to form a STNOSfinFET.

Said STNOSfinFET device can be prepared according to a procedure that resembles the one for preparation of the FGfinFET. Starting with a SOI substrate comprising active silicon fins 313 a sacrificial layer 328 of for example silicongermanium is grown. Subsequently a siliconnitride layer 316, a siliconoxide layer 318 and a polysilicon layer 320 are deposited. From hereon the processing is continued as described for the FGfinFET starting with etching of the gate stack defined by layers 316, 318, 320 and ending with the salicidation layer 338.

Although the non-volatile memory device of the present invention has been shown and described with respect to certain embodiments, those skilled in the art will be able to devise and prepare equivalents and modifications. The present invention includes all such equivalents and modifications and is limited only by the claims.

1. A non-volatile memory device comprising: a substrate, a first layer including a charge storage region and a second layer including a charge-tunneling region comprising a gap, said second layer being arranged in between said substrate and said first layer.

2. A non-volatile memory device according to claim 1, characterized in that the gap extends through the entire charge-tunneling region.

3. A non-volatile memory device according to claim 1, characterized in that the gap comprises a gas or liquid.

4. A non-volatile memory device according to claim 1, characterized in that said first layer comprises an electrically conducting material.

5. A non-volatile memory device according to claim 1, characterized in that said first layer comprises an electrically insulating material.

6. A method for manufacturing a non-volatile memory device, comprising the steps of: providing a substrate, depositing a sacrificial layer on first selected parts of the substrate, forming on first selected parts of said sacrificial layer a stack of layers comprising a first layer having a charge storage region and selectively removing second selected parts of the sacrificial layer, thereby forming a gap in between said first layer and the substrate.

7. A method according to claim 6, characterized in that the sacrificial layer comprises silicon and germanium.

8. A method according to claim 6, characterized in that the method further comprises the step of sealing the gap.

9. A method according to claim 8, characterized in that the non-volatile memory device comprises a transistor and the step of sealing said gap includes forming offset spacers, adjacent to said stack of layers, said offset spacers being used for sealing the gap and definition of source and drain impurity implantation of the transistor.

10. A method according to claim 7, characterized in that said gap is filled with a gas or liquid before the sealing step is finished.

11. An apparatus having embedded non-volatile memory including a device according to claim 1.

12. An apparatus having stand-alone non-volatile memory including a device according to claim 1.
